(19) United States
(12) Patent Application Publication
(10) Pub. No.: US 2026/0358917 A1
(43) Pub. Date: Nov. 12, 2026

(54) ANTENNA DEVICE WITH PIEZOELECTRIC TOUCH FUNCTION

(71) Applicant: Unictron Technologies Corporation, Hsin-Chu (TW)

(72) Inventors: Chih-Shen Chou, Miaoli County (TW); Hsiang-Cheng Yang, Taoyuan City (TW); Chih-Hsien Liao, Taoyuan City (TW); Sheng-Hung WU, Hsinchu City (TW); Chih-Chi Yen, Hsinchu County (TW)

(73) Assignee: Unictron Technologies Corporation, Hsin-Chu (TW)

(21) Appl. No.: 19/253,988

(22) Filed: Jun. 30, 2025

(30) Foreign Application Priority Data
May 9, 2025 (TW) 114117558

(51) Int. Cl. G06F 3/041; H03K 17/96

(52) U.S. Cl. CPC G06F 3/0414; H03K 17/964

(57) ABSTRACT

An antenna device includes a piezoelectric substrate, a first conductive layer, a positive electrode of a pressure touch layer, a second conductive layer, and a negative electrode of the pressure touch layer. The piezoelectric substrate is arranged to provide a piezoelectric touch function. The first conductive layer and the positive electrode of the pressure touch layer are located at a top of the piezoelectric substrate. The second conductive layer and the negative electrode of the pressure touch layer are located at the top of the piezoelectric substrate. A part of a bottom of the piezoelectric substrate is connected to the positive electrode of the pressure touch layer, and the other part of the bottom of the piezoelectric substrate is connected to the negative electrode of the pressure touch layer.

### BACKGROUND OF THE INVENTION

### 1. Field of the Invention

The present invention is related to integrated technologies of an antenna function and a touch function, and more particularly, to an antenna device with a piezoelectric touch function.

### 2. Description of the Prior Art

With the development of wireless communication technologies, a portable electronic device (e. g., a smartphone and a wireless earphone) is typically equipped with a communication module including an antenna, for performing long/short-range data transmission via a wireless fidelity (Wi-Fi) function and/or a Bluetooth (BT) function of the communication module. A chip antenna may be utilized to reduce an overall size of the portable electronic device. For some existing portable electronic devices, two separate components respectively corresponding to the touch function and the antenna function (e.g., a touch sensor and an antenna device) are arranged in different layers through a multi-layer structural design in order to reduce interference. The disadvantage is that the fabrication process of the multi-layer structure is considerably complex, and the manufacturing cost is relatively high.

A novel antenna device that can integrate the piezoelectric touch function and the antenna function into the same component is urgently needed.

### SUMMARY OF THE INVENTION

It is therefore one of the objectives of the present invention to provide an antenna device with a piezoelectric touch function, which can integrate multiple conductive layers and a pressure touch layer into the same chip antenna via a piezoelectric ceramic material, in order to address the above-mentioned issues.

According to an embodiment of the present invention, an antenna device is provided. The antenna device comprises a piezoelectric substrate, a first conductive layer, a positive electrode of a pressure touch layer, a second conductive layer, and a negative electrode of the pressure touch layer. The piezoelectric substrate is arranged to provide piezoelectric touch functionality. The first conductive layer and the positive electrode of the pressure touch layer are located at a top of the piezoelectric substrate. The second conductive layer and the negative electrode of the pressure touch layer are located at the top of the piezoelectric substrate. A part of a bottom of the piezoelectric substrate is connected to the positive electrode of the pressure touch layer, and the other part of the bottom of the piezoelectric substrate is connected to the negative electrode of the pressure touch layer.

One of the benefits of the antenna device proposed by the present invention is that a pressure touch function and an antenna function can be integrated into the same component with a single layer. That is, during the manufacturing process of an electronic device, the antenna device of the present invention only needs to be directly disposed on a circuit board of the electronic device, thereby enabling the simultaneous implementation of both an antenna and a touch interface. Compared with an existing method that respectively mounts two separate components corresponding to the antenna and the touch interface on the circuit board, the present invention simplifies the manufacturing process of the antenna device and significantly reduces the production cost. In addition, the piezoelectric touch technology adopted by the antenna device of the present invention offers higher accuracy and higher sensitivity, enabling the detection of subtle pressure changes. More particularly, the piezoelectric ceramic material used in the antenna device of the present invention has a compact structure, allowing for high-performance miniaturized designs and enabling the antenna device to be installed in a space-constrained electronic device (e.g., a wireless BT earphone). The piezoelectric ceramic material also provides superior high-temperature resistance and electromagnetic interference (EMI) immunity, making the antenna device suitable for operation in certain extreme environments.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an antenna device according to an embodiment of the present invention.

FIG. 2 is a diagram illustrating a layout of the antenna device shown in FIG. 1 that is disposed on a printed circuit board according to an embodiment of the present invention.

FIG. 3 is a diagram illustrating an antenna and piezoelectric touch system according to an embodiment of the present invention.

### DETAILED DESCRIPTION

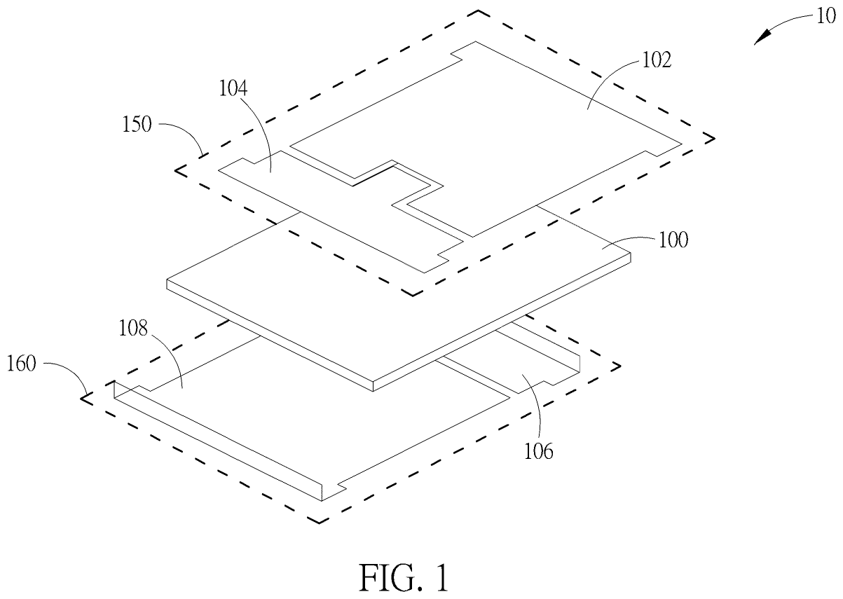

FIG. 1 is a diagram illustrating an antenna device 10 according to an embodiment of the present invention, wherein the antenna device 10 may be a chip antenna. As shown in FIG. 1, the antenna device 10 may include a piezoelectric substrate 100, a first conductive layer and a positive electrode of a pressure touch layer (labeled as “102” in FIG. 1), and a second conductive layer and a negative electrode of the pressure touch layer (labeled as “104” in FIG. 1), wherein the first conductive layer and the second conductive layer can provide a transceiving function for wireless signals of an antenna. The piezoelectric substrate 100 may be implemented by a material that can perform a conversion between mechanical energy and electrical energy (e.g., a piezoelectric ceramic material), and may be arranged to provide a piezoelectric touch function. As a result, the mechanical energy caused by pressure-induced deformation can be directly converted into electrical energy via the piezoelectric substrate 100, without applying an additional voltage to the antenna device 10. In addition, the first conductive layer and the second conductive layer are designed on the piezoelectric substrate 100, which enables the antenna device 10 to simultaneously be equipped with a pressure touch function and an antenna function. For example, a user may perform at least one pressing operation upon the piezoelectric substrate 100 in order to generate pressure change on the pressure touch layer, and thereby generate a voltage difference VD including a positive voltage V+ and a negative voltage V− via the piezoelectric substrate 100. The voltage difference VD is output to a subsequent circuit (e.g., a touch integrated circuit (IC) ) via the positive electrode and the negative electrode of the pressure touch layer, for being converted into a digital signal and then undergoing associated processing.

In this embodiment, each of the first conductive layer, the positive electrode of the pressure touch layer, the second conductive layer, and the negative electrode of the pressure touch layer is located at a top 150 of the piezoelectric substrate 100. It should be noted that the present invention adopts a surface-mount technology (SMT) to dispose the antenna device 10 on a printed circuit board (PCB), and both the positive electrode and the negative electrode of the pressure touch layer are required to arrange a portion of the conductor at a bottom 160 of the piezoelectric substrate 100 for signal transmission with the PCB. For example, a part of the bottom 160 of the piezoelectric substrate 100 (labeled as “106” in FIG. 1) may be connected to the positive electrode of the pressure touch layer, and the other part of the bottom 160 of the piezoelectric substrate 100 (labeled as “108” in FIG. 1) may be connected to the negative electrode of the pressure touch layer.

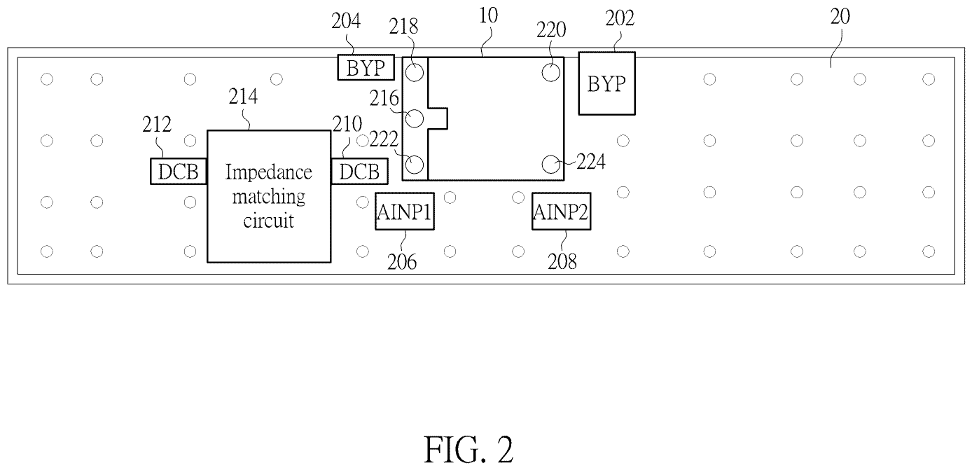

FIG. 2 is a diagram illustrating a layout of the antenna device 10 shown in FIG. 1 that is disposed on a PCB 20 according to an embodiment of the present invention. As shown in FIG. 2, the antenna device 10 may include multiple pins 216, 218, 220, 222, and 224. Multiple impedance matching circuits may be disposed on the pin 218, the pin 220, and/or positions of the PCB 20 that are adjacent to the antenna device 10 (e. g., an impedance matching circuit 214), and may be arranged to adjust impedance of the antenna device 10. For example, the multiple impedance matching circuits may compensate for impedance deviations of the antenna device 10 resulting from environmental factors. The pins 216 and 218 may be a signal input terminal and a signal output terminal, respectively, and may be arranged to receive/transmit wireless signals over the air. The pins 222 and 224 may represent the positive electrode and the negative electrode of the pressure touch layer, respectively, and may be coupled to a voltage output terminal 206 (labeled as “AINP1” in FIG. 2) and a voltage output terminal 208 (labeled as “AINP2” in FIG. 2). After at least one pressing operation is performed upon the piezoelectric substrate 100 for generating the voltage difference VD, the positive voltage V+ and the negative voltage V− included in the voltage difference VD may be transmitted to a subsequent circuit via the voltage output terminals 206 and 208, respectively. In addition, multiple bypass capacitors 202 and 204 (labeled as “BYP” in FIG. 2) may be disposed on the PCB 20, and may be adjacent to the antenna device 10. Multiple direct current (DC) blocking capacitors 210 and 212 (labeled as “DCB” in FIG. 2) may be disposed on the PCB 20 for blocking the voltage difference VD.

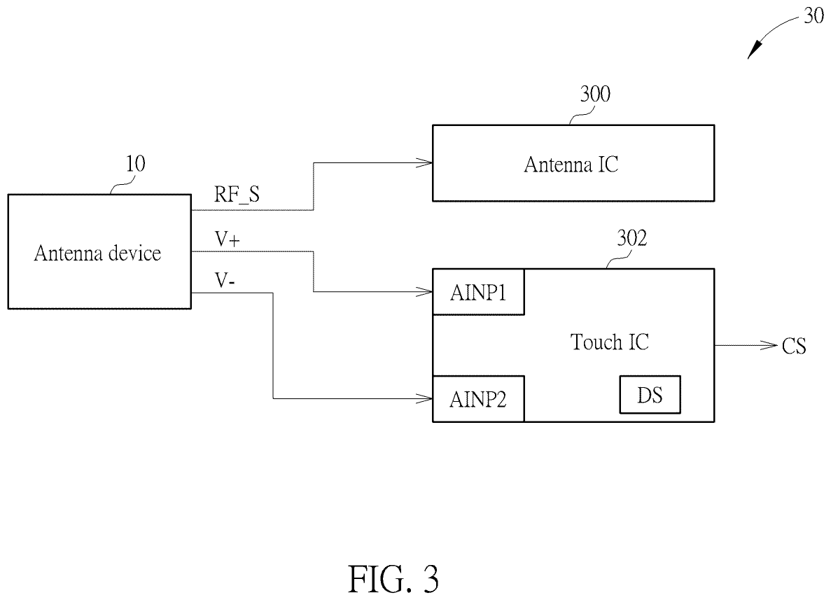

FIG. 3 is a diagram illustrating an antenna and piezoelectric touch system 30 according to an embodiment of the present invention, wherein the antenna and piezoelectric touch system 30 may be included in an electronic device. As shown in FIG. 3, the antenna and piezoelectric touch system 30 may include the antenna device 10 shown in FIG. 1, an antenna IC 300, and a touch IC 302. The antenna device 10 may input a wireless signal RF_S (e.g., a high-frequency signal with 2.4 GHz) to the antenna IC 300 for performing associated processing. For example, the antenna IC 300 may include a wireless transceiver circuit and a processor. The wireless transceiver circuit may process the wireless signal RF_S in order to obtain a received frame/data packet. In some embodiments, the wireless transceiver circuit may process a frame/data packet to be transmitted in order to obtain a corresponding signal for acting as a wireless signal, and transmit the wireless signal via the antenna device 10.

The touch IC 302 may be a micro control unit (MCU), and may be coupled to the voltage output terminal 206 (labeled as “AINP1” in FIG. 3) and the voltage output terminal 208 (labeled as “AINP2” in FIG. 3). After outputting the voltage difference VD to the touch IC 302 via the voltage output terminals 206 and 208, the touch IC 302 may convert the voltage difference VD into a digital signal DS, and process the digital signal DS via internal circuits in order to generate a control signal CS for controlling the electronic device. For example, under a situation where the electronic device is a wireless Bluetooth (BT) earphone, in response to a user performing one pressing operation upon the piezoelectric substrate 100, the wireless BT earphone may perform a music playback operation and/or a music pause operation according to the control signal CS. In response to the user performing two pressing operations upon the piezoelectric substrate 100, the wireless BT earphone may perform a track switching operation according to the control CS in order to switch to the next track. In response to the user performing three pressing operations upon the piezoelectric substrate 100, the wireless BT earphone may switch to the previously played track according to the control CS.

In summary, the antenna device proposed by the present invention can integrate a pressure touch function and an antenna function into the same component with a single layer. That is, during the manufacturing process of an electronic device, the antenna device of the present invention only needs to be directly disposed on a circuit board of the electronic device, thereby enabling the simultaneous implementation of both an antenna and a touch interface. Compared with an existing method that respectively mounts two separate components corresponding to the antenna and the touch interface on the circuit board, the present invention simplifies the manufacturing process of the antenna device and significantly reduces the production cost. In addition, the piezoelectric touch technology adopted by the antenna device of the present invention offers higher accuracy and higher sensitivity, enabling the detection of subtle pressure changes. More particularly, the piezoelectric ceramic material used in the antenna device of the present invention has a compact structure, allowing for high-performance miniaturized designs and enabling the antenna device to be installed in a space-constrained electronic device (e.g., a wireless BT earphone). The piezoelectric ceramic material also provides superior high-temperature resistance and electromagnetic interference (EMI) immunity, making the antenna device suitable for operation in certain extreme environments.

Those skilled in the art will readily observe that numerous modifications and alterations of the device and method may be made while retaining the teachings of the invention. Accordingly, the above disclosure should be construed as limited only by the metes and bounds of the appended claims.

1. An antenna device, comprising:
a piezoelectric substrate, arranged to provide a piezoelectric touch function;
a first conductive layer and a positive electrode of a pressure touch layer, located at a top of the piezoelectric substrate;
a second conductive layer and a negative electrode of the pressure touch layer, located at the top of the piezoelectric substrate; and
two conductor parts located at a bottom of the piezoelectric substrate for connecting the antenna device to a printed circuit board (PCB);
wherein one conductor part is connected to the positive electrode of the pressure touch layer, and the other conductor part is connected to the negative electrode of the pressure touch layer.

2. The antenna device of claim 1, wherein the antenna device is a chip antenna.

3. The antenna device of claim 1, wherein the piezoelectric substrate is a piezoelectric ceramic material.

4. The antenna device of claim 1, wherein a voltage difference is generated by performing at least one pressing operation upon the piezoelectric substrate, and the voltage difference is output through the positive electrode of the pressure touch layer and the negative electrode of the pressure touch layer.

5. The antenna device of claim 4, wherein the voltage difference is output to a touch integrated circuit (IC) for converting into a digital signal.

6. The antenna device of claim 4, wherein the antenna device is disposed on the PCB; and multiple direct current (DC) current blocking capacitors are further disposed on the PCB for blocking the voltage difference.

7. The antenna device of claim 6, wherein multiple bypass capacitors are further disposed on the PCB, and the multiple bypass capacitors are adjacent to the antenna device.

8. The antenna device of claim 1, further comprising:
multiple impedance matching circuits, arranged to adjust impedance of the antenna device.
